(19) United States
(12) Patent Application Publication
(10) Pub. No.: US 2024/0334804 A1
(43) Pub. Date: Oct. 3, 2024

(54) SOLAR CELL AND METHOD OF MANUFACTURING SOLAR CELL

(71) Applicant: HONDA MOTOR CO., LTD., Tokyo (JP)

(72) Inventors: Masahiro SASHIDA, Saitama (JP); Masaru NAKANISHI, Saitama (JP); Kohei KAWASHIMA, Saitama (JP); Tadahiro SHIBA, Saitama (JP)

(21) Appl. No.: 18/444,789

(22) Filed: Feb. 19, 2024

(30) Foreign Application Priority Data
Mar. 28, 2023 (JP) 2023-051314

(51) Int. Cl. H10K 85/10; H10K 30/40; H10K 85/60

(52) U.S. Cl. CPC H10K 85/113; H10K 30/40; H10K 85/626; H10K 85/657

(57) ABSTRACT

Provided is a solar cell comprising a negative electrode, an electron transport layer, an active layer, a hole transport layer, and a positive electrode that are sequentially laminated, wherein the active layer comprises an organic donor material and an organic acceptor material and has a phase separation structure having an interface length per μm² of 70 μm or more and 100 μm or less.

This application is based on and claims the benefit of priority from Japanese Patent Application No. 2023-051314, filed on 28 Mar. 2023, the content of which is incorporated herein by reference.

### BACKGROUND OF THE INVENTION

### Field of the Invention

The present invention relates to a solar cell and a method of manufacturing a solar cell.

### Related Art

In recent years, solar cells that contribute to improvement in energy efficiency have been researched and developed to ensure that more people have access to affordable, reliable, sustainable, and advanced energy.

There is known a solar cell in which a negative electrode, an electron transport layer, an active layer, a hole transport layer, and a positive electrode are sequentially laminated, and the active layer includes an organic donor material and an organic acceptor material (for example, see Patent Document 1).
Patent Document 1: Japanese Unexamined Patent Application, Publication No. 2020-13879

### SUMMARY OF THE INVENTION

However, it is desirable to improve power generation efficiency of the solar cell.

An object of the present invention is to provide a solar cell capable of improving power generation efficiency.

A first aspect of the present invention relates to a solar cell including a negative electrode, an electron transport layer, an active layer, a hole transport layer, and a positive electrode that are sequentially laminated, in which the active layer includes an organic donor material and an organic acceptor material and has a phase separation structure having an interface length per μm² of 70 μm or more and 100 μm or less.

A second aspect of the present invention relates to the solar cell as described in the first aspect, in which the organic donor material is a compound represented by the following chemical formula:

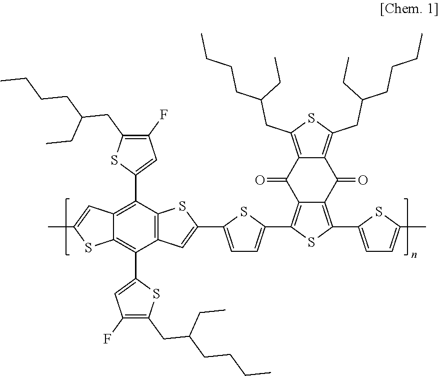

and the organic acceptor material is a compound represented by the following chemical formula:

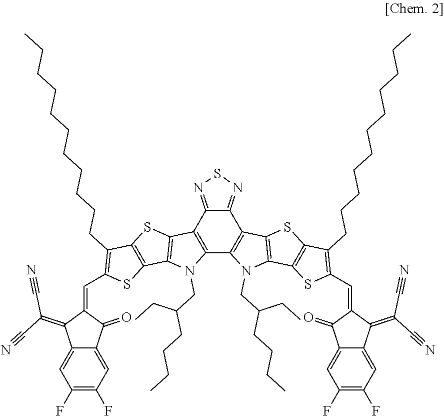 [SMILES: CCCCCCCCCCCc1c(/C=C2\C(=O)c3cc(F)c(F)cc3C2=C(C#N)C#N)sc2c1sc1c3c4nsnc4c4c5sc6c(CCCCCCCCCCC)c(/C=C7\C(=O)c8cc(F)c(F)cc8C7=C(C#N)C#N)sc6c5n(CC(CC)CCCC)c4c3n(CC(CC)CCCC)c21]

A third aspect of the present invention relates to a method of manufacturing the solar cell as described in the first or second aspect, the method including applying a coating liquid containing the organic donor material, the organic acceptor material, a first solvent, and a second solvent to form the active layer, in which the organic donor material and the organic acceptor material have a lower solubility in the second solvent than in the first solvent.

A fourth aspect of the present invention relates to the method of manufacturing the solar cell as described in the third aspect, in which the first solvent is a halogen-based solvent, the second solvent is one or more solvents selected from the group consisting of diiodooctane, chloronaphthalene, dimethylformamide, dimethylbenzylamine, dichlorooctane and octanediol, and the content of the second solvent is 1.0 volume % or less.

A fifth aspect of the present invention relates to the method of manufacturing the solar cell as described in the fourth aspect, in which a temperature of an environment where the active layer is formed is 25° C. or higher and 40° C. or lower.

According to the present invention, a solar cell capable of improving power generation efficiency can be provided.

### BRIEF DESCRIPTION OF THE DRAWINGS

FIG. 1 is a cross-sectional view showing an example of a solar cell of the present embodiment;

FIG. 2 is a top view showing a phase separation structure of the active layer of FIG. 1; and

FIG. 3 is a graph showing a relationship between the interface lengths per μm² and the power generation efficiencies in the phase separation structures of the active layers.

### DETAILED DESCRIPTION OF THE INVENTION

Hereinafter, embodiments of the present invention will be described with reference to the accompanying drawings.

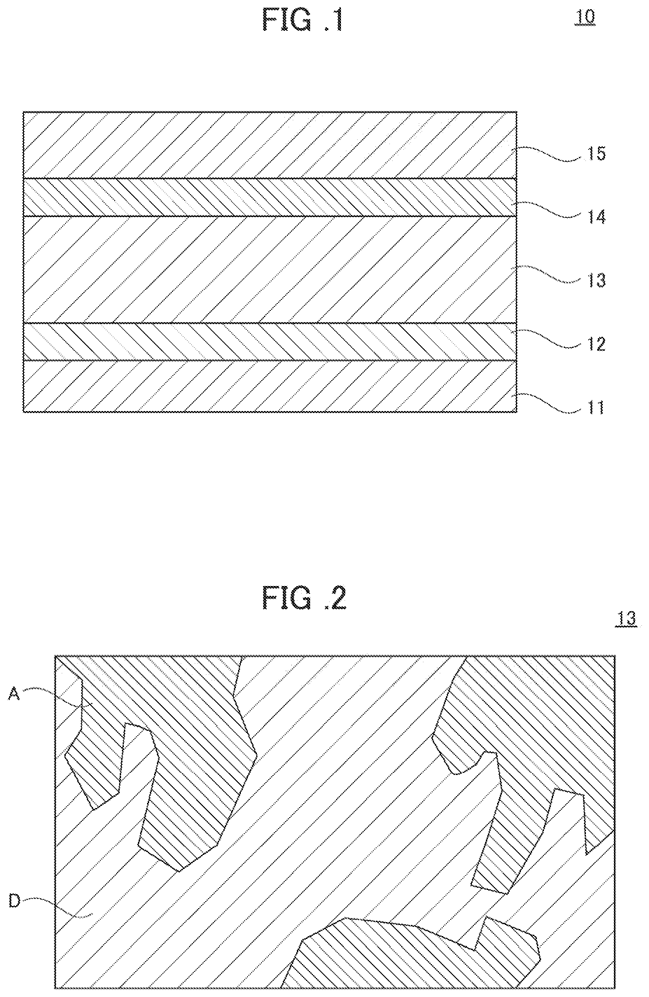

FIG. 1 shows an example of a solar cell of the present embodiment.

In a solar cell 10, a negative electrode 11, an electron transport layer 12, an active layer 13, a hole transport layer 14, and a positive electrode 15 are sequentially laminated.

As shown in FIG. 2, the active layer 13 includes the organic donor material D and the organic acceptor material A and has a phase separation structure. The interface length per μm² in the phase separation structure is 70 μm or more and 100 μm or less, and preferably 75 μm or more and 90 μm or less. When the interface length per μm² in the phase separation structure is less than 70 μm, the phase separation structure becomes coarse, and excitons generated by absorbing sunlight

are likely to be deactivated, so that the power generation efficiency of the solar cell 10 decreases. On the other hand, when the interface length per μm² of the phase separation structure exceeds 100 μm, the phase separation structure becomes fine and the separated charges are likely to recombine, so that the power generation efficiency of the solar cell 10 decreases.

The organic donor material D is not particularly limited as long as it is a p-type semiconductor material, and examples thereof include oligothiophene, polythiophene, polypyrrole, polyaniline, polyphenylene, polyphenylene vinylene, polythienylene vinylene, polyacetylene, polydiacetylene, tetrathiafulvalene, quinone, and tetracyanoquinodimethane. Among them, from the viewpoint of the power generation efficiency of the solar cell 10, compound PBDB-T-2F(PM6) (manufactured by Ossila) represented by the chemical formula:

[symbol]

### [Chem. 3]

is used.

The organic acceptor material A is not particularly limited as long as it is an n-type semiconductor material, and examples thereof include perfluoropentacene, perfluoro phthalocyanine, naphthalene tetracarboxylic anhydride, perylene tetracarboxylic anhydride, naphthalene tetracarboxylic diimide, and perylene tetracarboxylic diimide. Among them, from the viewpoint of the power generation efficiency of the solar cell 10, compound Y6 (manufactured by Sigma Aldrich) represented by the following chemical formula:

[symbol]

### [Chem. 4]

is used. Examples of the organic acceptor material A other than the above include BTP-eC9 (manufactured by Ossila), BTP-4C1-12 (manufactured by Ossila), BTP-4F-12 (manufactured by Ossila), compound Y7 (manufactured by Sigma Aldrich) in which F of Y6 is substituted with Cl, and BTO (manufactured by Brilliant Matters).

The thickness of the active layer 13 is not particularly limited, but is, for example, 90 nm or more and 110 nm or less.

The active layer 13 is formed by applying a coating liquid containing the organic donor material D, the organic acceptor material A, the first solvent, and the second solvent. Here, the organic donor material D and the organic acceptor material A have lower solubilities in the second solvent than in the first solvent. Thereby, the interface length per μm² in the phase separation structure of the active layer 13 can be adjusted.

The first solvent is not particularly limited, and examples thereof include halogen-based solvents such as chlorobenzene and chloroform.

The second solvent is not particularly limited as long as the interface length per μm² in the phase separation structure of the active layer 13 can be adjusted and examples thereof include diiodooctane, chloronaphthalene, dimethylformamide, dimethylbenzylamine, dichlorooctane, and octanediol. A combination of two types or more may be used.

The content of the second solvent in the coating liquid is 1.0 volume % or less, and preferably 0.1 volume % or more and 0.6 volume % or less. When the content of the second solvent in the coating liquid is 1.0 volume % or less, the power generation efficiency of the solar cell 10 increases.

The temperature of the environment where the active layer 13 is formed is preferably 25° C. or higher and 40° C. or lower. When the temperature of the environment where the active layer 13 is formed is 25° C. or higher and 40° C. or lower, the power generation efficiency of the solar cell 10 increases.

The environment where the active layer 13 is formed may be the ambient atmosphere, but is preferably a nitrogen atmosphere. This increases the power generation efficiency of the solar cell 10.

The oxygen concentration in the nitrogen atmosphere is not particularly limited, but is, for example, 1 ppm or less. The dew point of the nitrogen atmosphere is not particularly limited, but is, for example, −70° C. or higher and −50° C. or lower.

The negative electrode 11 is a metal electrode. The metal constituting the metal electrode is not particularly limited, and examples thereof include aluminum, silver, and gold.

The thickness of the negative electrode 11 is not particularly limited, but is, for example, 150 nm or more and 200 nm or less.

Examples of the method for forming the negative electrode 11 include a vacuum vapor deposition method and a solution coating method.

The negative electrode 11 may be a transparent electrode.

The material constituting the electron transport layer 12 is not particularly limited, but examples thereof include 2,9-dimethyl-4,7-diphenyl-1,10-phenanthroline (BCP), bis-3,6-(3,5-di-4-pyridylphenyl)-2-methylpyrimidine (B4PyMPM). Among them, poly(9,9-bis(3′-(N,N-dimethyl)-N-ethylammonium-propyl-2,7-fluorene)-alt-2,7-(9,9-dioctylfluorene))dibromide (PFN-Br) is preferable.

The thickness of the electron transport layer 12 is not particularly limited, but is, for example, 5 nm or more and 30 nm or less.

Examples of the method for forming the electron transport layer 12 include a vacuum vapor deposition method and a solution coating method.

Examples of the material constituting the hole transport layer 14 include, but are not limited to, polythiophene, poly(3,4-ethylenedioxythiophene) (PEDOT), polyaniline, N,N′-di(1-naphthyl)-N,N′-diphenyl-(1,1′-biphenyl)-4,4′-diamine (NPB), hexaazatriphenylenehexacarbonitrile (HAT-CN), and tetraphenyldibenzoperiflanthene (DBP). Among them, poly(3,4-ethylenedioxythiophene)/polystyrene sulfonic acid (PEDOT/PSS) is preferable.

The thickness of the hole transport layer 14 is not particularly limited, but is, for example, 8 nm or more and 15 nm or less.

Examples of the method for forming the hole transport layer 14 include a vacuum vapor deposition method and a solution coating method.

The positive electrode 15 is a transparent electrode. The material constituting the transparent electrode is not particularly limited, but examples thereof include indium tin oxide (ITO), indium zinc oxide (IZO), aluminum-doped zinc oxide (AZO), gallium-doped zinc oxide (GZO), zinc oxide (ZnO), and fluorine-doped tin oxide (SnO₂:F). Among them, ITO is preferable from the viewpoint of availability.

The thickness of the positive electrode 15 is not particularly limited, but is, for example, 100 nm or more and 300 nm or less.

The positive electrode 15 may be formed on a transparent substrate.

The material constituting the transparent substrate is not particularly limited, and examples thereof include glass and resin.

The thickness of the transparent substrate is not particularly limited, but is, for example, 0.5 mm or more and 1 mm or less.

A negative electrode buffer layer may be formed between the negative electrode 11 and the electron transport layer 12, or a positive electrode buffer layer may be formed between the positive electrode 15 and the hole transport layer 14. Further, a hole trapping layer may be formed between the electron transport layer 12 and the active layer 13, or an electron trapping layer may be formed between the hole transport layer 14 and the active layer 13.

Further, the negative electrode 11 may be a transparent electrode, and the positive electrode 15 may be a metal electrode.

Although the embodiments of the present invention have been described above, the present invention is not limited to the above-described embodiments, and the above-described embodiments may be appropriately modified within the scope of the present invention.

### EXAMPLES

Hereinafter, Examples of the present invention will be described, but the present invention is not limited to these Examples.

### Example 1

(Preparation of Active Layer Coating Liquid) Compound PM6 (organic donor material) and compound Y6 (organic acceptor material) were weighed at a mass ratio of 1:1.2, and dissolved in chloroform (first solvent) to a concentration of 8 mg/ml. Next, chloronaphthalene (second solvent) was added so that the content became 0.5 volume % to obtain an active layer coating liquid.

### (Preparation of Solar Cell)

A 15 nm-thick PEDOT/PSS film (hole transport layer) was formed by spin coating in the ambient atmosphere on an ITO film of a glass substrate having a 150 nm-thick ITO film (positive electrode) formed thereon. Next, an active layer coating liquid was applied onto the PEDOT/PSS film by a spin coating method under a nitrogen atmosphere to form an active layer having a thickness of 100 nm. Here, the nitrogen atmosphere has a temperature of 24.5° C., an oxygen concentration of 1 ppm, and a dew point of −40° C. Next, a PFN-Br film (electron transport layer) having a thickness of 5 nm was formed on the active layer by spin coating under a nitrogen atmosphere. Next, an Al film (negative electrode) was formed on the PFN-Br film by vacuum vapor deposition. Next, under a nitrogen atmosphere, the solar cell was sealed with a glass cap using an ultraviolet curing adhesive to obtain a solar cell. The interface length per μm² in the phase separation structure of the active layer was 70 μm.

### Example 2

A solar cell was obtained in the same manner as in Example 1 except that the temperature of the nitrogen atmosphere for forming the active layer was changed to 30° C. The interface length per μm² in the phase separation structure of the active layer was 100 μm.

### Example 3

A solar cell was obtained in the same manner as in Example 1 except that the temperature of the nitrogen atmosphere for forming the active layer was changed to 29.5° C. The interface length per μm² in the phase separation structure of the active layer was 83 μm.

### Comparative Example 1

A solar cell was obtained in the same manner as in Example 1 except that the content of the second solvent was changed to 1 volume % in the preparation of the active layer coating liquid. The interface length per μm² in the phase separation structure of the active layer was 52 μm.

### Comparative Example 2

A solar cell was obtained in the same manner as in Comparative Example 1 except that the temperature of the nitrogen atmosphere for forming the active layer was changed to 25° C. The interface length per μm² in the phase separation structure of the active layer was 52 μm.

### Comparative Example 3

A solar cell was obtained in the same manner as in Comparative Example 1 except that the temperature of the nitrogen atmosphere for forming the active layer was changed to 30° C. The interface length per μm² in the phase separation structure of the active layer was 62 μm.

### [Interface Length Per μm² in Phase Separation Structure of Active Layer]

A phase image of the active layer formed at the time of manufacturing a solar cell was obtained by using an atomic force microscope (AFM), and then the phase image was binarized. Next, the length of the boundary between the organic donor material and the organic acceptor material was determined from the phase image subjected to the binarization processing, and then divided by the area of the phase image to calculate the interface length per μm² in the phase separation structure of the active layer. Here, in the binary processing of the phase image, a position where the mass ratio of the organic donor material and the organic acceptor material in the active layer coating liquid is equal to the area ratio of the phase image was used as a threshold value.

### [Power Generation Efficiency of Solar Cells]

The power generation efficiencies of the solar cells were measured in accordance with IEC61215, 61836 (JIS C61215, MQT06, JIS C8904). At this time, the irradiance of the light source was set to 1,000 W/m² in accordance with JIS C8904-3. The temperature of the solar cell (module temperature) was set to 25° C.

Table 1 shows the evaluation results of the power generation efficiencies of the solar cells.

TABLE 1

| | Example | | | Comparative Example | | |
|---|---|---|---|---|---|---|
| | 1 | 2 | 3 | 1 | 2 | 3 |
| Content of second solvent in coating | 0.5 | 0.5 | 0.5 | 1.0 | 1.0 | 1.0 |
| liquid [volume %] | | | | | | |
| Temperature of nitrogen atmosphere | 24.5 | 30 | 29.5 | 19.5 | 25 | 30 |
| [° C.] | | | | | | |
| Interface length per μm² in phase | 70 | 100 | 83 | 55 | 66 | 105 |
| separation structure of active layer | | | | | | |
| [μm] | | | | | | |
| Power generation efficiency [%] | 12 | 12 | 13 | 7 | 10 | 11 |

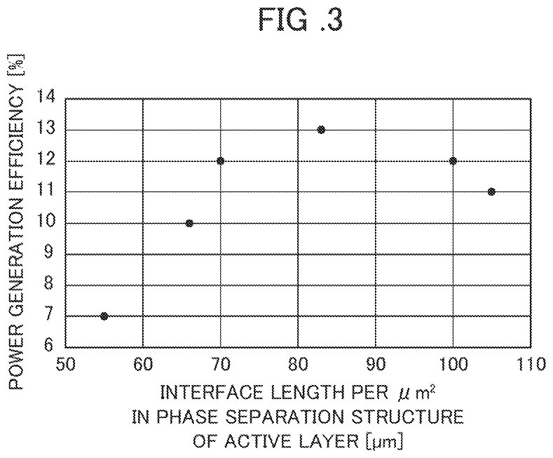

FIG. 3 shows the relationship between the interface lengths per μm² and the power generation efficiencies in the phase separation structures of the active layers.

From Table 1 and FIG. 3, it is understood that the solar cells of Examples 1 to 3 had high power generation efficiencies. On the other hand, in the solar cells of Comparative Examples 1 to 3, since the interface lengths per μm² in the phase separation structures of the active layers were 55 μm, 66 μm, and 105 μm, respectively, the power generation efficiencies were low.

### EXPLANATION OF REFERENCE NUMERALS

10 Solar cell
11 Negative electrode
12 Electron transport layer
13 Active layer
14 Hole transport layer
15 Positive electrode
D Organic donor material
A Organic acceptor material

What is claimed is:

1. A solar cell comprising a negative electrode, an electron transport layer, an active layer, a hole transport layer, and a positive electrode that are sequentially laminated,
wherein the active layer comprises an organic donor material and an organic acceptor material and has a phase separation structure having an interface length per μm² of 70 μm or more and 100 μm or less.

2. The solar cell according to claim 1,
wherein the organic donor material is a compound represented by the following chemical formula: 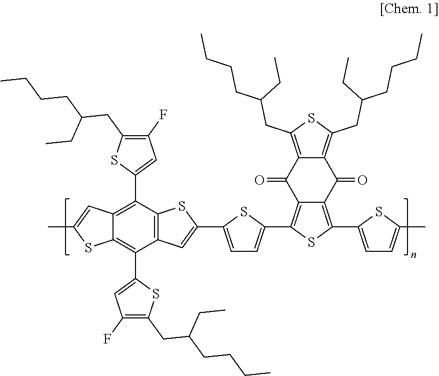
and the organic acceptor material is a compound represented by the following chemical formula:

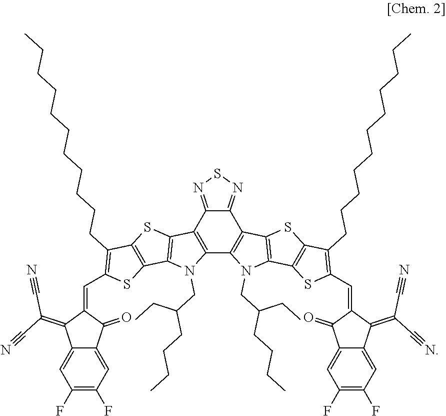 [SMILES: CCCCCCCCCCCc1c(/C=C2\C(=O)c3cc(F)c(F)cc3C2=C(C#N)C#N)sc2c1sc1c3c4nsnc4c4c5sc6c(CCCCCCCCCCC)c(/C=C7\C(=O)c8cc(F)c(F)cc8C7=C(C#N)C#N)sc6c5n(CC(CC)CCCC)c4c3n(CC(CC)CCCC)c21]

3. A method of manufacturing the solar cell according to claim 1,
the method comprising applying a coating liquid containing the organic donor material, the organic acceptor material, a first solvent, and a second solvent to form the active layer,
wherein the organic donor material and the organic acceptor material have a lower solubility in the second solvent than in the first solvent.

4. The method of manufacturing the solar cell according to claim 3,
wherein the first solvent is a halogen-based solvent,
the second solvent is one or more solvents selected from the group consisting of diiodooctane, chloronaphthalene, dimethylformamide, dimethylbenzylamine, dichlorooctane and octanediol, and
a content of the second solvent is 1.0 volume % or less.

5. The method of manufacturing the solar cell according to claim 3, wherein a temperature of an environment where the active layer is formed is 25° C. or higher and 40° C. or lower.
